(19) United States
(12) Patent Application Publication
(10) Pub. No.: US 2025/0145858 A1
(43) Pub. Date: May 8, 2025

(54) SLURRY COMPOSITION FOR POLISHING METAL FILM

(71) Applicant: KCTECH CO., LTD., Gyeonggi-do (KR)

(72) Inventors: Jin Sook HWANG, Gyeonggi-do (KR); Se Jin LIM, Gyeonggi-do (KR)

(73) Assignee: KCTECH CO., LTD., Gyeonggi-do (KR)

(21) Appl. No.: 18/938,286

(22) Filed: Nov. 6, 2024

(30) Foreign Application Priority Data
Nov. 7, 2023 (KR) 10-2023-0153070

(51) Int. Cl. C09G 1/02; B24B 37/04; C08F 226/02

(52) U.S. Cl. CPC C09G 1/02; B24B 37/044; C08F 226/02

(57) ABSTRACT

A slurry composition for polishing a metal film, and a method for chemical mechanical polishing (CMP) of a substrate using the slurry composition are provided. The slurry composition includes a polishing regulator, and the polishing regulator includes a copolymer comprising a polymer with an allylamine-based structural unit and a polymer with a structural unit including at least one element among sulfur (S), phosphorus (P), and nitrogen (N).

### CROSS-REFERENCE TO RELATED APPLICATION

This application claims the benefit of Korean Patent Application No. 10-2023-0153070, filed on Nov. 7, 2023, in the Korean Intellectual Property Office, the entire disclosure of which is incorporated herein by reference for all purposes.

### BACKGROUND

### 1. Field

One or more embodiments relate to a slurry composition for polishing a metal film, which includes a novel polishing regulator compound.

### 2. Description of Related Art

Chemical mechanical polishing (CMP) is a process in which an arbitrary material is removed from a surface of a wafer of a microelectronic device and in which the surface is polished by coupling a physical process such as polishing with a chemical process such as oxidation or chelation. A polishing composition (i.e., a slurry composition for polishing a metal film) for polishing a metal layer such as tungsten on a semiconductor substrate may include abrasive particles suspended in an aqueous solution, a catalyst, an oxidizing agent, a polishing regulator, a corrosion inhibitor, and the like.

As the feature size of a semiconductor device continues to be reduced, it has become difficult to meet local and global planarization requirements in CMP operations such as tungsten CMP operations. Array erosion, plug and line recessing (dishing), and tungsten etching defects are known to compromise planarization and overall device integrity. Tungsten etching/corrosion may degrade the electrical performance or even cause device failure. Thus, there is a desire in the art for a CMP slurry composition that provides an enhanced planarization during CMP operations such as tungsten CMP operations.

### SUMMARY

One or more embodiments provide a slurry composition for polishing a metal film and a method of performing polishing using the slurry composition that may inhibit tungsten etching, and the like, due to an excellent inhibition effect on various metal films, such as tungsten (W), molybdenum (Mo), or copper (Cu), that may suppress dishing and erosion for each pattern of the metal film and other films, and that may realize a high selectivity and high polishing rate.

However, goals to be achieved by the present disclosure are not limited to those described above, and other goals not mentioned above can be clearly understood by one of ordinary skill in the art from the following description.

According to an aspect, there is provided a slurry composition for polishing a metal film, including a polishing regulator. The polishing regulator may include a copolymer comprising a polymer with an allylamine-based structural unit and a polymer with a structural unit including at least one element among sulfur (S), phosphorus (P), and nitrogen (N).

According to another aspect, there is provided a method for chemical mechanical polishing (CMP) of a substrate, including bringing the substrate into contact with a slurry composition for polishing a metal film, and polishing the substrate with the slurry composition. The slurry composition may include a polishing regulator. The polishing regulator may include a copolymer comprising a polymer with an allylamine-based structural unit and a polymer with a structural unit including at least one element among sulfur (S), phosphorus (P), and nitrogen (N).

According to embodiments, a slurry composition for polishing a metal film may reduce or prevent pattern defects of fine patterns while maintaining a polishing rate of the metal film and may reduce or prevent recesses by suppressing chemical etching of the metal film. In addition, during a polishing of a wafer including a metal film and an insulating film, a polishing rate of the metal film may be increased and a polishing rate of the insulating film may be reduced, thereby realizing a high selectivity, and suppressing dishing and erosion for each pattern.

It should be understood that the effects of the present disclosure are not limited to the effects described above, but include all effects that can be inferred from the configuration of the disclosure described in the detailed description or claims of the present disclosure.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 illustrates erosion evaluation results of slurry compositions for polishing metal films of Examples 1 to 16 and Comparative Examples 1 to 7; and

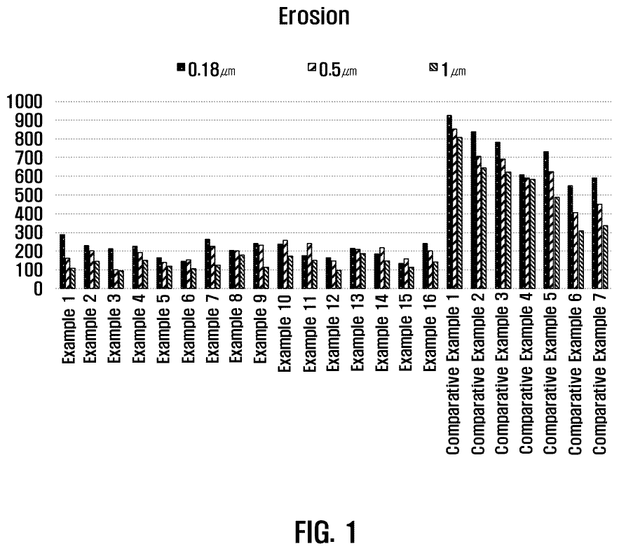

FIG. 2 illustrates recess evaluation results of the slurry compositions of Examples 1 to 16 and Comparative Examples 1 to 7.

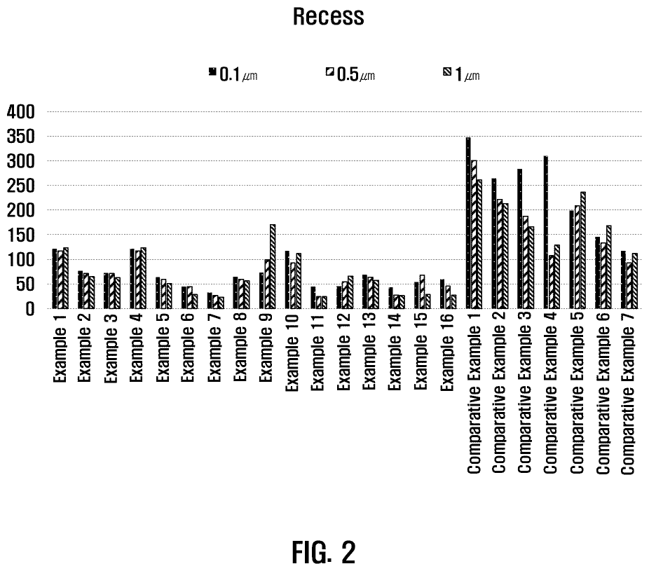

### DETAILED DESCRIPTION

Hereinafter, embodiments will be described in detail with reference to the accompanying drawings. However, various alterations and modifications may be made to the embodiments. Here, the embodiments are not meant to be limited by the descriptions of the present disclosure. The embodiments should be understood to include all changes, equivalents, and replacements within the idea and the technical scope of the disclosure.

The terminology used herein is for the purpose of describing particular embodiments only and is not intended to be limiting. The singular forms “a,” “an,” and “the” are intended to include the plural forms as well, unless the context clearly indicates otherwise. It will be further understood that the terms “comprises/comprising” and/or “includes/including” when used herein, specify the presence of stated features, integers, steps, operations, elements, components, and/or groups thereof but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

In addition, in the description of embodiments, detailed description of well-known related structures or functions will be omitted when it is deemed that such description will cause ambiguous interpretation of the present disclosure.

Furthermore, the terms first, second, A, B, (a), and (b) may be used to describe components of the embodiments. These terms are used only for the purpose of discriminating one component from another component, and the nature, the sequences, or the orders of the components are not limited by the terms.

Components included in one embodiment and components having a common function will be described using the same names in other embodiments. Unless otherwise mentioned, the description on one embodiment may be applicable to other embodiments and duplicated descriptions will be omitted for conciseness.

It will be understood throughout the whole specification that, when one part “includes” or “comprises” one component, the part does not exclude other components but may further include the other components.

According to an embodiment, a slurry composition for polishing a metal film, which includes a polishing regulator, is provided. The polishing regulator may include a copolymer comprising a polymer with an allylamine-based structural unit and a polymer with a structural unit including at least one element among sulfur (S), phosphorus (P), and nitrogen (N).

The polishing regulator may include, for example, a copolymer represented by the following Chemical Formula 1:

-[(A)ₗ-(Y)ₘ]ₙ- [Chemical Formula 1]

In Chemical Formula 1, A is an allylamine-based structural unit (monomer), Y is a structural unit including at least one of sulfur (S), phosphorus (P), and nitrogen (N), 1 and m are each an integer of “5” to “1,000,” and n is an integer of “1” to “3,000.”

In particular, the allylamine-based structural unit A may include an allylamine-based structural unit, for example, allylamine hydrochloride, allylamine-acetate, diallylamine-acetate, allylamine, diallylamine hydrochloride, diallyldimethylammonium chloride, methyldiallylamine, diallylamine, methoxycarbonylated allylamine, methylcarbonylated allylamine acetate, carboxymethylated allylamine, acrylamide, and 3-chloro-2-hydroxypropylated diallylamine hydrochloride.

The structural unit Y may include a structural unit, for example, N-acetyl-allylamine, N-carbamoyl allylamine, diallylamine hydrochloride, diallylamine-acetate, diallylamine, diallyldimethylammonium chloride, methoxycarbonylated allylamine, methylcarbonylated allylamine acetate, carboxymethylated allylamine, acrylamide, 3-chloro-2-hydroxypropylated diallylamine hydrochloride, allylamine, allylamine hydrochloride, allylamine-acetate, and methyldiallylamine.

Here, the allylamine-based structural unit A and the structural unit Y may be different from each other. Desirably, a combination of the allylamine-based structural unit A and the structural unit Y may be a combination of allylamine and N-acetyl-allylamine, or a combination of allylamine and N-carbamoyl allylamine.

The copolymer of the polishing regulator formed as described above may correspond to Chemical Formula 2 or Chemical Formula 3 shown below.

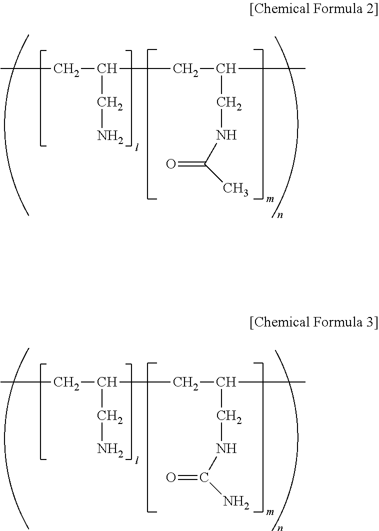

In Chemical Formulae 2 and 3, 1 and m are each an integer of “5” to “1,000,” and n is an integer of “1” to “3,000.”

An amount of the polishing regulator included in the slurry composition may be greater than or equal to 0.001% and less than or equal to 2%, based on the total weight of the slurry composition. For example, the amount of the polishing regulator in the slurry composition may be greater than or equal to 0.002% and less than or equal to 1%, greater than or equal to 0.003% and less than or equal to 0.5%, and greater than or equal to 0.005% and less than or equal to 0.1%, but is not limited thereto.

In addition, the slurry composition may include a liquid carrier, and abrasive particles dispersed in the liquid carrier.

The liquid carrier may be used to facilitate an application of an abrasive and any optional chemical additives to a surface of a substrate (metal film) to be polished. The liquid carrier may include, for example, alcohols, such as methanol and ethanol, ethers, such as dioxane and tetrahydrofuran, water, and/or mixtures thereof. Desirably, water may be used, and more desirably, deionized water may be included and used.

The abrasive particles may include any suitable abrasive material, such as metal oxide particles, ceramic particles, and the like. The metal oxide particles may include, for example, silica and/or alumina abrasive particles, and more desirably, colloidal silica particles. The colloidal silica particles may be silica particles fabricated through a wet process and may be in an aggregated state or a non-aggregated state. Aggregated particles may be a plurality of particles collected or bonded together to form aggregates (secondary particles) having a generally irregular shape.

The abrasive particles may have an average particle size of greater than or equal to about 2 nanometers (nm) and less than or equal to 300 nm, desirably greater than or equal to about 5 nm and less than or equal to 200 nm, or greater than or equal to about 10 nm and less than or equal to 100 nm, and more desirably greater than or equal to about 20 nm and less than or equal to 50 nm.

In addition, the slurry composition may substantially include any suitable amount of abrasive particles. For example, an amount of abrasive particles in the slurry composition may be greater than or equal to about 0.01% by weight (wt %) and less than or equal to 30 wt %, desirably greater than or equal to 0.1 wt % and less than or equal to 10 wt %, more desirably greater than or equal to 0.2 wt % and less than or equal to 5 wt %, and most desirably greater than or equal to 0.3 wt % and less than or equal to 2 wt %.

The slurry composition may further include a catalyst, an oxidizing agent, and a corrosion inhibitor, in addition to the polishing regulator, the liquid carrier, and the abrasive particles.

Types of the catalyst may correspond to an iron-containing catalyst that is soluble in a liquid carrier. Specifically, the catalyst may include, for example, iron (II or III) nitrate, iron (II or III) sulfate, iron (II or III) halide including at least one of fluoride, chloride, bromide, and iodide, iron hydrochloride, iron cyanide, iron citrate, ferrous ammonium sulfate, iron oxide, and the like.

The iron-containing catalyst may be included in an amount of greater than or equal to 0.01% and less than or equal to 0.3%, desirably in an amount of greater than or equal to 0.02% and less than or equal to 0.2%, and more desirably in an amount of greater than or equal to 0.03% and less than or equal to 0.1%, based on the total weight of the slurry composition, however, embodiments are not limited thereto.

In addition, the oxidizing agent may be added to a polishing composition during a process of preparing a slurry composition or immediately before chemical mechanical polishing (CMP). Types of the oxidizing agent may include, for example, an inorganic or organic per-compound and may desirably correspond to hydrogen peroxide.

The oxidizing agent may be included in an amount of greater than or equal to 0.1% and less than or equal to 2%, and desirably in an amount of greater than or equal to 0.2% and less than or equal to 1%, based on the total weight of the slurry composition, however, embodiments are not limited thereto.

The corrosion inhibitor may include, for example, histidine, arginine, methionine, acetamine, pyrazine, betaine, serine, cysteine, glutamine, glutamic acid, glycine, alanine, valine, leucine, isoleucine, lysine, threonine, aspartic acid, asparagine, phenylalanine, dioxyphenylalanine, tyrosine, tryptophan, ornithine, citrulline, homoserine, triiodotyrosine, thyroxine, and proline, and may desirably include glutamine, and the like. The corrosion inhibitor may be included in an amount of less than or equal to 1%, desirably in an amount of less than or equal to 0.5%, and more desirably in an amount of less than or equal to 0.2%, based on the total weight of the slurry composition, however, embodiments are not limited thereto.

In addition, pH of the slurry composition may be greater than or equal to 3 and less than or equal to 6.5. If the pH is less than 3, a polishing speed for a metal film may decrease and a polishing speed for an insulating film may increase, which may make it difficult to realize a high selectivity. If the pH exceeds 6.5, a chemical etching speed for a metal film may increase, which may cause a secondary issue such as a reduction in dishing and erosion during a polishing of a pattern wafer.

According to an embodiment, a method for CMP of a substrate may be provided. The method may include step S1 of bringing the substrate into contact with a slurry composition for polishing a metal film, and step S2 of polishing the substrate with the slurry composition. The polishing regulator may include a copolymer comprising a polymer with an allylamine-based structural unit and a polymer with a structural unit including at least one element among sulfur (S), phosphorus (P), and nitrogen (N).

The slurry composition used in step S1 may be substantially the same as the slurry composition described above. The substrate used in the method is not particularly limited, but may be a metal film including, but is not limited to, a tungsten (W) layer, a molybdenum (Mo) layer, a copper (Cu) layer, a silicon (Si) layer, a titanium (Ti) layer, a titanium nitride (TiN) layer, a cobalt (Co) layer, a ruthenium (Ru), a silicon dioxide (SiO₂) layer, or a silicon nitride (SiN) layer, which is generally used for CMP.

In addition, the slurry composition may further include a liquid carrier, abrasive particles dispersed in the liquid carrier, a catalyst, an oxidizing agent, and a corrosion inhibitor, and pH of the slurry composition formed as described above may be greater than or equal to 3 and less than or equal to 6.5.

After step S1, in step S2, the substrate may be polished to remove at least one layer from the substrate. Here, the layer on the substrate may correspond to, for example, a W layer, a Mo layer, a Cu layer, a Si layer, a Ti layer, a TiN layer, a Co layer, a Ru layer, a SiO₂ layer, or a SiN layer.

Hereinafter, a configuration of the present disclosure and effects thereof will be described in greater detail through examples and comparative examples. However, the examples are intended to more particularly explain the present disclosure and the scope of the present disclosure is not limited to the examples.

### EXAMPLE

### 1) Preparation Example: Preparation of Slurry Composition for Polishing Metal Film

To distilled water, a predetermined amount of each of an abrasive, a catalyst, a polishing regulator, a corrosion inhibitor, and an oxidizing agent according to a composition 5 shown in Table 1 below were added, and the mixture was stirred, to prepare a slurry composition for polishing a metal film. Colloidal silica particles were used as particles, ultrapure water was used as a solvent, glutamine was used as a tungsten corrosion inhibitor, a material represented by a structural formula shown below was used as a tungsten polishing regulator, hydrogen peroxide was used as an oxidizing agent, and iron nitrate was used as a 10 catalyst, to prepare the slurry composition. Specific compositions are shown in Table 1 (Examples 1 to 16 and Comparative Examples 1 to 7) below.

TABLE 1

| | | | | | Tungsten | | | | | |
|---|---|---|---|---|---|---|---|---|---|---|
| | | | | | polishing | | Tungsten corrosion | | | |
| | Particles and | | Catalyst and | | regulator and | | inhibitor and | | Oxidizing agent | |
| | amount | | amount | | amount | | amount | | and amount | |
| Items | (wt %) | | (wt %) | | (wt %) | | (wt %) | | (wt %) | |
| Example | Silica | 0.50% | Iron | 0.08% | a | 0.005% | Glutamine | 0.18% | Hydrogen | 0.50% |
| 1 | | | nitrate | | | | | | peroxide | |
| Example | Silica | 0.50% | Iron | 0.08% | a | 0.01% | Glutamine | 0.18% | Hydrogen | 0.50% |
| 2 | | | nitrate | | | | | | peroxide | |
| Example | Silica | 0.50% | Iron | 0.08% | a | 0.03% | Glutamine | 0.18% | Hydrogen | 0.50% |
| 3 | | | nitrate | | | | | | peroxide | |
| Example | Silica | 0.50% | Iron | 0.08% | a | 0.03% | — | — | Hydrogen | 0.50% |
| 4 | | | nitrate | | | | | | peroxide | |
| Example | Silica | 0.30% | Iron | 0.08% | a | 0.01% | Glutamine | 0.18% | Hydrogen | 0.50% |
| 5 | | | nitrate | | | | | | peroxide | |
| Example | Silica | 0.40% | Iron | 0.08% | a | 0.02% | Glutamine | 0.18% | Hydrogen | 0.50% |
| 6 | | | nitrate | | | | | | peroxide | |
| Example | Silica | 0.50% | Iron | 0.08% | b | 0.005% | Glutamine | 0.18% | Hydrogen | 0.50% |
| 7 | | | nitrate | | | | | | peroxide | |
| Example | Silica | 0.50% | Iron | 0.08% | b | 0.01% | Glutamine | 0.18% | Hydrogen | 0.50% |
| 8 | | | nitrate | | | | | | peroxide | |
| Example | Silica | 0.50% | Iron | 0.08% | b | 0.03% | Glutamine | 0.18% | Hydrogen | 0.50% |
| 9 | | | nitrate | | | | | | peroxide | |
| Example | Silica | 0.50% | Iron | 0.08% | b | 0.03% | — | — | Hydrogen | 0.50% |
| 10 | | | nitrate | | | | | | peroxide | |
| Example | Silica | 0.30% | Iron | 0.08% | b | 0.01% | Glutamine | 0.18% | Hydrogen | 0.50% |
| 11 | | | nitrate | | | | | | peroxide | |
| Example | Silica | 0.40% | Iron | 0.08% | b | 0.02% | Glutamine | 0.18% | Hydrogen | 0.50% |
| 12 | | | nitrate | | | | | | peroxide | |
| Example | Silica | 0.50% | Iron | 0.08% | c | 0.03% | — | — | Hydrogen | 0.50% |
| 13 | | | nitrate | | | | | | peroxide | |
| Example | Silica | 0.50% | Iron | 0.08% | d | 0.03% | — | — | Hydrogen | 0.50% |
| 14 | | | nitrate | | | | | | peroxide | |
| Example | Silica | 0.50% | Iron | 0.08% | e | 0.03% | — | — | Hydrogen | 0.50% |
| 15 | | | nitrate | | | | | | peroxide | |
| Example | Silica | 0.50% | Iron | 0.08% | f | 0.03% | — | — | Hydrogen | 0.50% |
| 16 | | | nitrate | | | | | | peroxide | |
| Comparative | Silica | 0.50% | Iron | 0.08% | — | — | Glutamine | 0.18% | Hydrogen | 0.50% |
| Example | | | nitrate | | | | | | peroxide | |
| 1 | | | | | | | | | | |
| Comparative | Silica | 0.50% | Iron | 0.08% | g | 0.01% | Glutamine | 0.18% | Hydrogen | 0.50% |
| Example | | | nitrate | | | | | | peroxide | |
| 2 | | | | | | | | | | |
| Comparative | Silica | 0.50% | Iron | 0.08% | g | 0.03% | Glutamine | 0.18% | Hydrogen | 0.50% |
| Example | | | nitrate | | | | | | peroxide | |
| 3 | | | | | | | | | | |
| Comparative | Silica | 0.50% | Iron | 0.08% | g | 0.03% | — | — | Hydrogen | 0.50% |
| Example | | | nitrate | | | | | | peroxide | |
| 4 | | | | | | | | | | |
| Comparative | Silica | 0.50% | Iron | 0.08% | h | 0.03% | — | — | Hydrogen | 0.50% |
| Example | | | nitrate | | | | | | peroxide | |
| 5 | | | | | | | | | | |
| Comparative | Silica | 0.50% | Iron | 0.08% | i | 0.03% | — | — | Hydrogen | 0.50% |
| Example | | | nitrate | | | | | | peroxide | |
| 6 | | | | | | | | | | |
| Comparative | Silica | 0.50% | Iron | 0.08% | j | 0.03% | — | — | Hydrogen | 0.50% |
| Example | | | nitrate | | | | | | peroxide | |
| 7 | | | | | | | | | | |

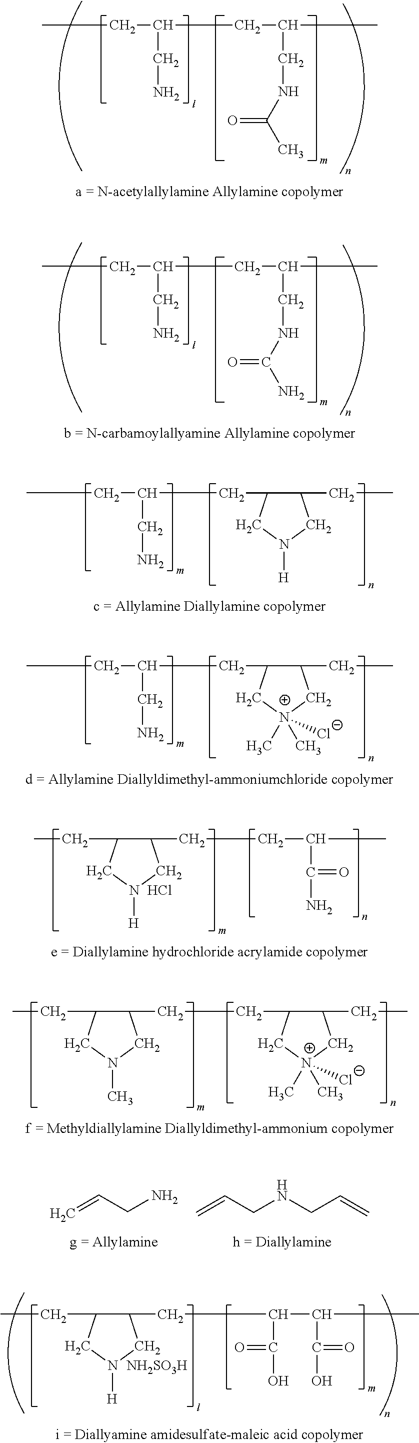

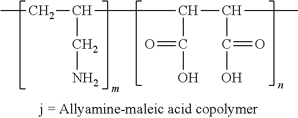

### 2) Experimental Example: Evaluation of Erosion, Recess, and Oxide Film Removal Rate

Erosion, recess, and oxide film removal rates for the slurry compositions prepared in Examples 1 to 16 and Comparative Examples 1 to 7 were evaluated using an AP 300 d polishing device at a pressure of 2.5 psi and a carrier/platen polishing speed of 100 rpm, and the results thereof are shown in Table 2.

TABLE 2

| | | | | | | | Polishing | | |
|---|---|---|---|---|---|---|---|---|---|
| | Erosion (Density | | | Recess (Density | | | rate (RR) | Polishing | |
| | 50%) | | | 50%) | | | of | rate (RR) | |
| | 0.18 | 0.5 | | 0.1 | 0.5 | | tungsten | of oxide | Selectivity |
| Items | μm | μm | 1 μm | μm | μm | 1 μm | (W) | (Ox) | (W/Ox) |
| Example 1 | 289 | 161 | 107 | 121 | 117 | 123 | 6,115 | 25 | 245 |
| Example 2 | 228 | 201 | 145 | 77 | 71 | 65 | 5,823 | 29 | 201 |
| Example 3 | 213 | 101 | 93 | 72 | 71 | 63 | 5,512 | 23 | 240 |
| Example 4 | 226 | 193 | 150 | 121 | 117 | 123 | 5,728 | 26 | 220 |
| Example 5 | 164 | 139 | 119 | 64 | 59 | 51 | 5,411 | 25 | 216 |
| Example 6 | 145 | 152 | 104 | 45 | 45 | 29 | 5,567 | 24 | 232 |
| Example 7 | 263 | 227 | 124 | 33 | 26 | 23 | 6,015 | 25 | 241 |
| Example 8 | 204 | 202 | 179 | 65 | 60 | 56 | 5,779 | 23 | 251 |
| Example 9 | 239 | 232 | 115 | 73 | 99 | 170 | 5,587 | 28 | 200 |
| Example 10 | 236 | 257 | 173 | 117 | 93 | 112 | 5,689 | 26 | 219 |
| Example 11 | 175 | 241 | 150 | 45 | 24 | 24 | 5,403 | 24 | 225 |
| Example 12 | 165 | 146 | 98 | 46 | 54 | 66 | 5,522 | 25 | 221 |
| Example 13 | 216 | 208 | 186 | 69 | 64 | 57 | 5,838 | 25 | 234 |
| Example 14 | 183 | 217 | 146 | 43 | 27 | 26 | 5,392 | 24 | 225 |
| Example 15 | 132 | 159 | 113 | 54 | 68 | 29 | 5,676 | 23 | 247 |
| Example 16 | 239 | 201 | 143 | 59 | 46 | 27 | 5,973 | 26 | 230 |
| Comparative | 926 | 853 | 808 | 347 | 300 | 261 | 6,317 | 80 | 79 |
| Example 1 | | | | | | | | | |
| Comparative | 839 | 706 | 644 | 264 | 222 | 213 | 6,210 | 76 | 82 |
| Example 2 | | | | | | | | | |
| Comparative | 783 | 692 | 623 | 283 | 187 | 166 | 5,116 | 77 | 66 |
| Example 3 | | | | | | | | | |
| Comparative | 607 | 591 | 584 | 310 | 108 | 129 | 5,382 | 67 | 80 |
| Example 4 | | | | | | | | | |
| Comparative | 733 | 626 | 488 | 199 | 209 | 237 | 6,018 | 73 | 82 |
| Example 5 | | | | | | | | | |
| Comparative | 548 | 406 | 308 | 146 | 133 | 168 | 5,867 | 74 | 79 |
| Example 6 | | | | | | | | | |
| Comparative | 590 | 452 | 335 | 117 | 93 | 112 | 5,771 | 75 | 77 |
| Example 7 | | | | | | | | | |

As shown in Table 2. it can be found that in the slurry compositions of Examples 1 to 16 including tungsten polishing regulators “a” to “f” within the scope of the present disclosure. crosion, and recesses were more suppressed in comparison to the slurry compositions of Comparative Examples 1 to 7 that did not include a polishing regulator or that include tungsten polishing regulators “g” to “j” beyond the scope of the present disclosure, and can also be found that low oxide film removal rates (Ox RR) were measured in comparison to the slurry compositions of Comparative Examples 1 to 7.

Thus, it is determined that the polishing regulator in the slurry composition includes a copolymer comprising a polymer with an allylamine-based structural unit and a polymer with a structural unit including at least one element among sulfur (S), phosphorus (P), and nitrogen (N), thereby having an influence on performance of the slurry composition, such as erosion, recess, and oxide film removal rates.

While the embodiments are described with reference to the drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order and/or if components in a described system, architecture, device, or circuit are combined in a different manner and/or replaced or supplemented by other components or their equivalents.

Therefore, other implementations, other embodiments, and equivalents to the claims are also within the scope of the following claims.

What is claimed is:

1. A slurry composition for polishing a metal film, the slurry composition comprising a polishing regulator,
wherein the polishing regulator comprises a copolymer comprising a polymer with an allylamine-based structural unit and a polymer with a structural unit comprising at least one element selected from a group consisting of sulfur (S), phosphorus (P), and nitrogen (N).

2. The slurry composition of claim 1, wherein the polishing regulator comprises a copolymer represented by Chemical Formula 1:
-[(A)ₗ-(Y)ₘ]ₙ- [Chemical Formula 1]
in Chemical Formula 1, A is an allylamine-based structural unit (monomer), Y is a structural unit including at least one of sulfur (S), phosphorus (P), and nitrogen (N), 1 and m are each an integer of “5” to “1,000,” and n is an integer of “1” to “3,000.”

3. The slurry composition of claim 1, wherein the allylamine-based structural unit comprises at least one allylamine-based structural unit selected from a group consisting of allylamine hydrochloride, allylamine-acetate, diallylamine-acetate, allylamine, diallylamine hydrochloride, diallyldimethylammonium chloride, methyldiallylamine, diallylamine, methoxycarbonylated allylamine, methylcarbonylated allylamine acetate, carboxymethylated allylamine, acrylamide, and 3-chloro-2-hydroxypropylated diallylamine hydrochloride.

4. The slurry composition of claim 1, wherein the structural unit comprises a structural unit selected from a group consisting of N-acetyl-allylamine, N-carbamoyl diallylamine hydrochloride, diallylamine-acetate, diallylamine, allylamine, diallyldimethylammonium chloride, methoxycarbonylated allylamine, methylcarbonylated allylamine acetate, carboxymethylated allylamine, acrylamide, 3-chloro-2-hydroxypropylated diallylamine hydrochloride, allylamine, allylamine hydrochloride, allylamine-acetate, and methyldiallylamine.

5. The slurry composition of claim 1, wherein the allylamine-based structural unit and the structural unit are different from each other.

6. The slurry composition of claim 1, wherein the copolymer comprises at least one copolymer selected from a group consisting of allylamine hydrochloride polymer/diallylamine hydrochloride polymer, allylamine-acetate polymer/diallylamine-acetate polymer, allylamine polymer/diallylamine polymer, allylamine polymer/diallyldimethylammonium chloride polymer, allylamine polymer/methoxycarbonylated allylamine polymer, allylamine polymer/methylcarbonylated allylamine acetate polymer, allylamine polymer/carboxymethylated allylamine polymer, diallylamine hydrochloride polymer/acrylamide polymer, diallyldimethyl-ammonium chloride polymer/acrylamide polymer, methyldiallylamine polymer/diallyldimethylammonium chloride polymer, diallyldimethylammonium chloride polymer/3-chloro-2-hydroxypropylated diallylamine hydrochloride polymer, allylamine polymer/N-acetylallylamine polymer, and allylamine polymer/N-carbamoyl allylamine polymer.

7. The slurry composition of claim 1, wherein the copolymer comprises a copolymer comprising an allylamine polymer/N-acetylallylamine polymer, which is represented by Chemical Formula 2, or 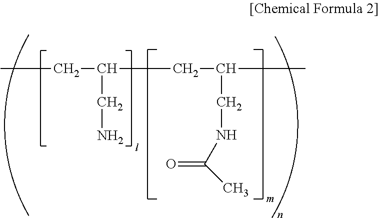
a copolymer comprising an allylamine polymer/N-carbamoyl allylamine polymer, which is represented by Chemical Formula 3: 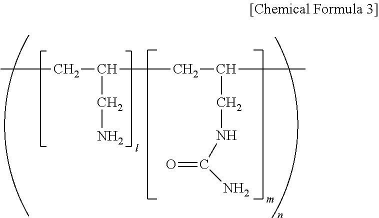
in Chemical Formulae 2 and 3, 1 and m are each an integer of “5” to “1,000,” and n is an integer of “1” to “3,000.”

8. The slurry composition of claim 1, wherein the slurry composition comprises:
a liquid carrier; and
abrasive particles dispersed in the liquid carrier.

9. The slurry composition of claim 1, wherein the abrasive particles comprise colloidal silica particles.

10. The slurry composition of claim 1, wherein the slurry composition comprises a catalyst and an oxidizing agent.

11. The slurry composition of claim 10, wherein
the catalyst comprises an iron-containing catalyst,
the oxidizing agent comprises hydrogen peroxide.

12. The slurry composition of claim 11, wherein the iron-containing catalyst comprises at least one selected from a group consisting of iron (II or III) nitrate, iron (II or III) sulfate, iron (II or III) halide, iron hydrochloride, iron cyanide, iron citrate, ferrous ammonium sulfate, and iron oxide.

13. The slurry composition of claim 1, wherein the slurry composition further comprises at least one corrosion inhibitor selected from a group consisting of histidine, arginine, methionine, acetamine, pyrazine, betaine, serine, cysteine, glutamine, glutamic acid, glycine, alanine, valine, leucine, isoleucine, lysine, threonine, aspartic acid, asparagine, phenylalanine, dioxyphenylalanine, tyrosine, tryptophan, ornithine, citrulline, homoserine, triiodotyrosine, thyroxine, and proline.

14. The slurry composition of claim 1, wherein pH of the slurry composition is greater than or equal to 3 and less than or equal to 6.5.

15. A method for chemical mechanical polishing (CMP) of a substrate, the method comprising:
bringing the substrate into contact with a slurry composition for polishing a metal film; and
polishing the substrate with the slurry composition,
wherein the slurry composition comprises a polishing regulator,
wherein the polishing regulator comprises a copolymer comprising a polymer with an allylamine-based structural unit and a polymer with a structural unit comprising at least one element selected from a group consisting of sulfur (S), phosphorus (P), and nitrogen (N).

16. The method of claim 15, wherein the substrate comprises a tungsten (W) layer, a molybdenum (Mo) layer, a copper (Cu) layer, a silicon (Si) layer, a titanium (Ti) layer, a titanium nitride (TiN) layer, a cobalt (Co) layer, a ruthenium (Ru), a silicon dioxide (SiO₂) layer, or a silicon nitride (SiN) layer.

17. The method of claim 15, wherein the slurry composition comprises a liquid carrier, abrasive particles dispersed in the liquid carrier, a catalyst, and an oxidizing agent.

18. The method of claim 15, wherein
the slurry composition further comprises a corrosion inhibitor that is glutamine, and
pH of the slurry composition is greater than or equal to 3 and less than or equal to 6.5.
